(19) United States
(12) Patent Application Publication
(10) Pub. No.: US 2024/0413010 A1
(43) Pub. Date: Dec. 12, 2024

(54) SEMICONDUCTOR STRUCTURE AND METHOD OF FORMING THE SAME

(71) Applicant: Taiwan Semiconductor Manufacturing Company, Ltd., Hsinchu (TW)

(72) Inventors: Yen Ju Wu, Hsinchu (TW); Chi-Lin Teng, Taichung City (TW); Cheng-Chin Lee, Taipei City (TW); Shao-Kuan Lee, Kaohsiung City (TW); Kai-Fang Cheng, Taoyuan City (TW); Hsin-Yen Huang, New Taipei City (TW); Hsiao-Kang Chang, Hsinchu City (TW)

(73) Assignee: Taiwan Semiconductor Manufacturing Company, Ltd., Hsinchu (TW)

(21) Appl. No.: 18/331,897

(22) Filed: Jun. 8, 2023

(51) Int. Cl. H01L 21/768; H01L 23/532

(52) U.S. Cl. CPC H01L 21/76843; H01L 21/76816; H01L 21/76826; H01L 21/76832; H01L 21/76877; H01L 23/53238

(57) ABSTRACT

A method of forming a semiconductor structure is provided. A first dielectric layer is formed over a substrate. A first metal pattern is formed through the first dielectric layer. A metal cap is formed over the first metal pattern. A surface portion of the metal cap is silicided to form a metal silicide pattern. A composite etch stop layer is formed on the first dielectric layer and the metal silicide pattern. A second dielectric layer is formed on the composite etch stop structure. A second metal pattern is formed through the second dielectric layer and the composite etch stop structure and landed on the metal silicide pattern.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, such scaling down also increases resistance-capacitance (RC) delay time and therefore affects the integrated circuit performance. Although the existing semiconductor structures have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 8 are cross-sectional views illustrating a method of forming a semiconductor structure in accordance with some embodiments of the disclosure.

FIG. 9 to FIG. 11 are cross-sectional views illustrating semiconductor structures in accordance with other embodiments of the disclosure.

FIG. 12 to FIG. 15 are cross-sectional views illustrating semiconductor structures in accordance with other embodiments of the disclosure.

FIG. 16 to FIG. 19 are cross-sectional views illustrating semiconductor structures in accordance with other embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments of the disclosure, a metal silicide is interspersed between a metal pattern and an overlying etch stop layer, so as to increase the adhesion between the metal pattern and the overlying etch stop layer, and therefore improve the reliability of the semiconductor structure.

A semiconductor structure and a method of forming the same are provided. The intermediate stages of forming a semiconductor structure of some embodiment are illustrated. The variations of the semiconductor structure are discussed. Throughout the various views and illustrative embodiments of the present disclosure, like reference numbers are used to designate like elements.

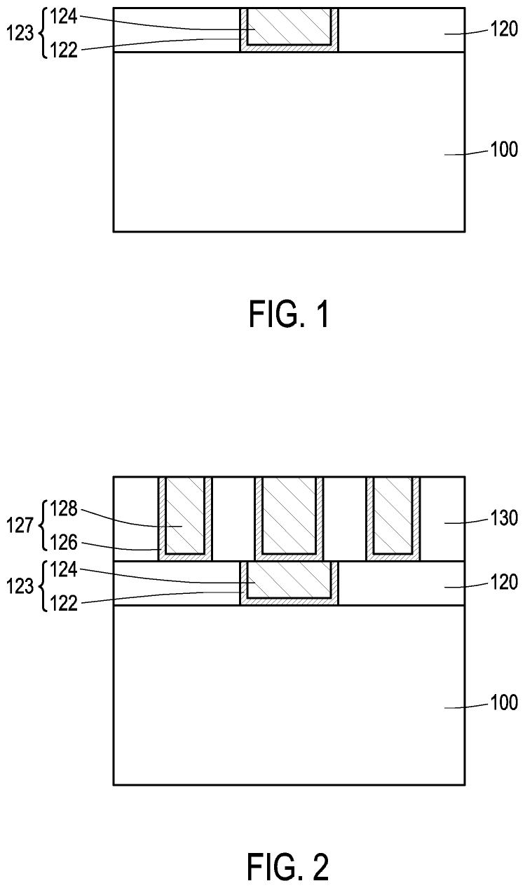

FIG. 1 to FIG. 8 are cross-sectional views illustrating a method of forming a semiconductor structure in accordance with some embodiments of the disclosure.

Referring to FIG. 1, a substrate 100 is provided. The substrate 100 may be a semiconductor substrate, such as a bulk semiconductor substrate, a semiconductor-on-insulator (SOI) substrate, or the like. The substrate 100 may be a silicon substrate, or may include a suitable semiconductor material such as SiGe, GaAs, or the like. The substrate 100 may include various doped regions depending on design requirements (e.g., p-type semiconductor substrate or n-type semiconductor substrate). The doped regions may be doped with p-type or n-type dopants. The dopant concentrations in various doped regions may be different. At least one integrated circuit such as a PMOS and/or an NMOS transistor (not shown) may be formed on the top surface of the semiconductor substrate. The transistor may be a planar metal-oxide-semiconductor field-effect transistor (MOSFET), a fin-type field-effect transistor (FinFET), a Gate All Around (GAA) transistor, or the like.

FIG. 1 further illustrates the formation of a dielectric layer 120 over the substrate 100. In an embodiment, the dielectric layer 120 includes a low-k material having a dielectric constant less than 3.5, less than about 3.0, less than about 2.5, or less than about 2.0. In some embodiments, the dielectric layer 120 may include carbon-doped silicon oxide, fluorine-doped silicon oxide, an organic low-k material, or a porous low-k material. In some embodiments, the dielectric layer 120 includes elements such as Si, O, C, N and/or H. For example, the low-k material includes SiOCH, SiOC, SiOCN or a combination thereof.

FIG. 1 further illustrates the formation of at least one metal pattern 123 in the dielectric layer 120. In some embodiments, the metal pattern 123 includes a barrier layer 122 and a metal feature 124. The barrier layer 122 may be disposed between each metal feature 124 and the dielectric layer 120 to prevent the material of the metal feature 124 from migrating to the underlying component such as the transistor. The barrier layer 122 may include Ta, TaN, Ti, TiN, CoW, the like, or a combination thereof. The metal feature 124 may include copper or copper alloy. In some embodiments, a seed layer is disposed between the barrier layer 122 and the metal feature 124, and the seed layer includes Cu. The metal feature 124 includes a metal contact or a metal line electrically connected to the underlying transistor. In some embodiments, the metal feature 124 is referred to as a copper feature 124, although it may also be formed of, or include, another conductive material, such as silver, gold, tungsten, aluminum, or the like. In some embodiments, the method for forming the metal pattern 123 may include forming an opening through the dielectric layer 120, forming a barrier material layer in the opening, depositing a thin seed layer of copper or copper alloy, and plating a copper layer in the opening. A chemical mechanical planarization (CMP) is then performed to remove excess layers outside of the opening, resulting in the structure as shown in FIG. 1. Throughout the description, the metal pattern 123 is referred to as a “zeroth metal pattern”.

FIG. 2 illustrates the formation of a dielectric layer 130 over the dielectric layer 120. In an embodiment, the dielectric layer 130 includes a low-k material having a dielectric constant less than 3.5, less than about 3.0, less than about 2.5, or less than about 2.0. In some embodiments, the dielectric layer 130 may include carbon-doped silicon oxide, fluorine-doped silicon oxide, an organic low-k material, or a porous low-k material. In some embodiments, the dielectric layer 130 includes elements such as Si, O, C, N and/or H. For example, the low-k material includes SiOCH, SiOC, SiOCN or a combination thereof.

In some embodiments, the dielectric constant or material of the dielectric layer 130 is substantially the same as the dielectric constant or material of the dielectric layer 120. However, the disclosure is not limited thereto. In other embodiments, the dielectric constant or material of the dielectric layer 130 may be different from (e.g., greater than or less than) the dielectric constant or material of the dielectric layer 120.

FIG. 2 further illustrates the formation of at least one metal pattern 127 in the dielectric layer 130. In some embodiments, the metal pattern 127 includes a barrier layer 126 and a metal feature 128. The barrier layer 126 may be disposed between each metal feature 128 and the dielectric layer 130 to prevent the material of the metal feature 128 from migrating to the underlying component such as the transistor. The barrier layer 126 may include Ta, TaN, Ti, TiN, CoW, the like, or a combination thereof. The metal feature 128 may include copper or copper alloy. In some embodiments, a seed layer is disposed between the barrier layer 126 and each metal feature 128, and the seed layer includes Cu. The metal feature 128 includes a metal line electrically connected to the metal feature 124. In some embodiments, the metal feature 128 is referred to as a copper feature 128, although it may also be formed of, or include, another conductive material, such as silver, gold, tungsten, aluminum, or the like. In some embodiments, the method for forming the metal pattern 127 may include forming an opening through the dielectric layer 130, forming a barrier material layer in the opening, depositing a thin seed layer of copper or copper alloy, and plating a copper layer in the opening. A chemical mechanical planarization (CMP) is then performed to remove excess layers outside of the opening, resulting in the structure as shown in FIG. 2. Throughout the description, the metal pattern 127 is referred to as a “first metal pattern”.

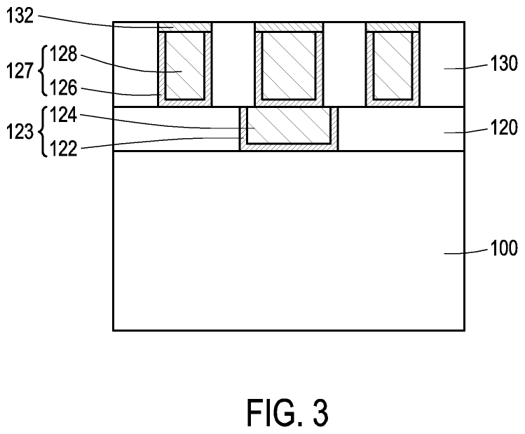

FIG. 3 illustrates the formation of at least one metal cap 132 in the dielectric layer 130 above the metal pattern 127. In some embodiments, the metal cap 132 is embedded within the dielectric layer 130 and in contact with the metal pattern 127. The material of the cap layer 132 is different from the material of the metal pattern 127. In some embodiments, the metal pattern 127 includes Cu, and the metal cap includes Co, Ni, Ti, W. Pt or a combination thereof. In some embodiments, the method of forming the metal cap 132 may include removing a portion of the metal pattern 127 to form a recess above the remaining metal pattern 127, and filling the recess with a metal cap material with a deposition process. In some embodiments, the recess may be formed by a selective etching process. In other embodiments, the recess may be formed by photolithography etching processes. A chemical mechanical planarization (CMP) is then performed to remove the metal cap material outside of the recess, resulting in the structure as shown in FIG. 3. In some embodiments, the top surface of the metal cap 132 is flushed with the top surface of the dielectric layer 130. However, the disclosure is not limited thereto. In other embodiments, the top surface of the metal cap 132 may be not flushed with (e.g., protruded from) the top surface of the dielectric layer 130, which will be described in other embodiments below. In some embodiments, the metal cap 132 has a thickness of about 10-50 angstroms, such as about 20-30 angstroms.

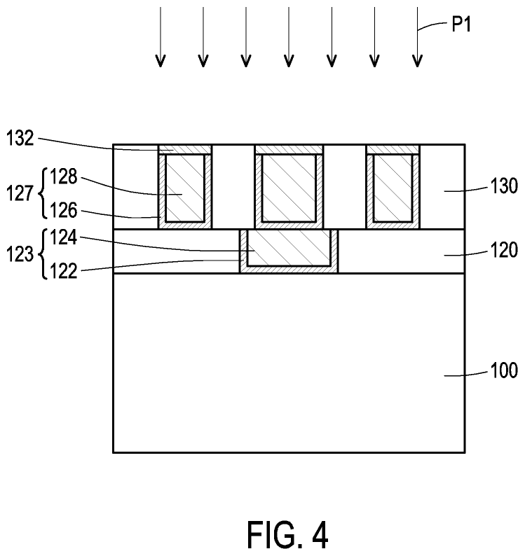

FIG. 4 to FIG. 6 illustrate the formation of at least one metal silicide pattern 134 on the metal cap 132. In some embodiments, the metal silicide pattern 134 is formed by siliciding or silicidizing a surface portion of the metal cap 132. Specifically, the metal silicide pattern 134 is formed by siliciding metal in the metal cap 132. In some embodiments, the metal silicide pattern 134 includes cobalt silicide (CoSix), nickel silicide (NiSx), titanium silicide (TiSix), tungsten silicide (WSix), platinum silicide (PtSix) or a combination thereof. In some embodiments, the formation of the metal silicide pattern 134 is performed in a deposition chamber, such as a plasma-enhanced chemical vapor deposition (PECVD) chamber.

In some embodiments, as shown in FIG. 4, a pre-treatment process P1 is performed to the surface of the metal cap 132. The pre-treatment process P1 is configured to remove residues from the surface of the metal cap 132. In some embodiments, the pre-treatment process Pl includes a pre-heating and pre-cleaning process. In some embodiments, the pre-heating and pre-cleaning process is performed at a temperature from about 280° C. to 360° C. (e.g., from about 320° C. to 340° C.) under a nitrogen-containing atmosphere. The nitrogen-containing atmosphere may include NH₃, N₂, H₂. Ar or a combination thereof.

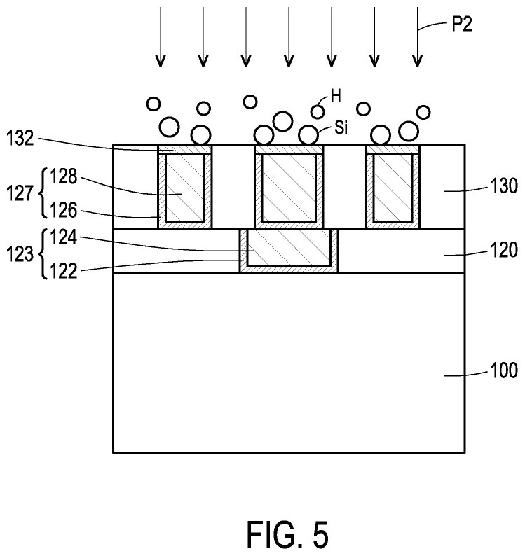

Thereafter, as shown in FIG. 5, the metal cap 132 is subjected to a silicon-containing atmosphere P2, so that silicon ions are adsorbed on the treated surface of the metal cap 132. In some embodiments, the silicon-containing atmosphere P2 includes SiH₄, Si(CH₃)₄, Si(CH₃)₄, Si(CH₃)₃H, Si(CH₃)₂H₂, Si₂H₆, Si₃Hₛ or a combination thereof. In some embodiments, when the silicon-containing atmosphere P2 includes SiH₄, such silicon-containing atmosphere P2 is referred to as a “silane soaking”. In some embodiments, the SiH₄ dissociate rate is degraded when using NH3 as a dilution gas at the silane soaking step, so as to control the metal silicide formation.

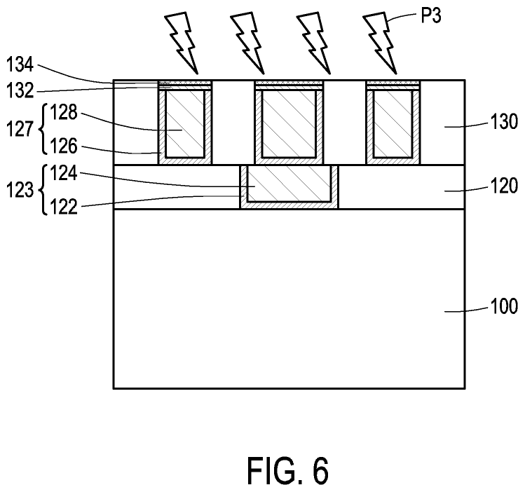

Afterwards, as shown in FIG. 6, a plasma process P3 is performed to react the silicon ions with metal in the surface portion of the metal cap 132. In some embodiments, the plasma process P3 is performed at a temperature from about 360° C. to 450° C. (e.g., from about 380° C. to 400° C.) under a nitrogen-containing atmosphere. The nitrogen-containing atmosphere may include NH₃, N₂, H₂, Ar or a combination thereof. In some embodiments, when the plasma process P3 includes NH₃, such plasma process P3 is referred to as a “NH₃ plasma pining”. In other embodiments, an UV pining and/or a thermal pinning may be used instead of the NH₃ plasma pining.

Upon the operations of FIG. 4 to FIG. 6, the metal silicide pattern 134 is formed above and in contact with the remaining metal cap 132. The operations of forming the metal silicide pattern 134 is called a low-temperature plasma self-aligned barrier (PSAB) process. The low-temperature PSAB process would lower the forming capability of metal silicide and the also reduce Rs impact. The metal silicide may also protect the underlying metal cap from being damaged during the subsequently ESL forming step. In some embodiments, the metal silicide pattern 134 has a thickness of about 2-15 angstroms, such as about 5-10 angstroms. In some embodiments, the silicon atom content of the metal silicide pattern 134 ranges from about 1 at % to 10 at %, such as from about 3 at % to 5 at %.

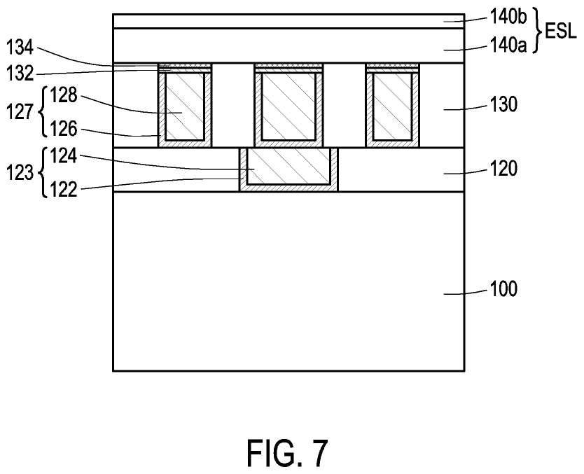

FIG. 7 illustrates the formation of a composite etch stop layer ESL on the dielectric layer 130 and the metal silicide pattern 134. In some embodiments, the composite etch stop layer ESL is in contact with the metal silicide pattern 134. In some embodiments, the composite etch stop layer ESL has a thickness of about 80-100 angstroms. For example, each layer of the composite etch stop layer ESL has a thickness of about 10-60 angstroms.

The composite etch stop layer ESL may be a single layer or have a multi-layer structure. In some embodiments, each layer of the composite etch stop layer ESL may have a dielectric constant equal to or greater than about 3.5. In some embodiments, the composite etch stop layer ESL includes SiCN, SiOC, SiC, SIN, AIN, A1₂O₃ or a combination thereof. The dielectric constant of a material is a measure of its ability to store electrical energy. The same composition material may have different dielectric constants depending on different atom contents of the composition and/or different forming parameters.

The composite etch stop layer ESL of the disclosure is also called a “low-k ESK scheme” because the lowermost layer of the composite etch stop layer ESL is approximately equal to or slightly higher than the dielectric constant of the underlying dielectric layer 130. In some embodiments, when the composite etch stop layer ESL has a multi-layer structure, the dielectric constant of the lowermost layer of the multi-layer structure is about 5-45% (e.g., 10-40% or 20-30%) higher than the dielectric constant of the underlying dielectric layer 130. In some embodiments, when the composite etch stop layer ESL has a multi-layer structure, the uppermost layer of the multi-layer structure is higher than the dielectric constant of the underlying layer(s) of the multi-layer structure. In some embodiments, when the composite etch stop layer ESL has a multi-layer structure, the dielectric constants of multiple layers are gradually increased away from the underlying dielectric layer.

In some embodiments, as shown in FIG. 7, the composite etch stop layer ESL includes a lower etch stop layer 140a and an upper etch stop layer 140b. In some embodiments, the lower etch stop layer 140a includes SiCN, and the upper etch stop layer 140b includes Al₂O₃. In some embodiments, the thickness of the lower etch stop layer 140a is greater than the thickness of the upper etch stop layer 140b. For example, the thickness ratio of the upper etch stop layer 140b to the lower etch stop layer 140a ranges from about 1/3 to 1/10.

In some embodiments, the dielectric constant of the lowermost etch stop layer (e.g., lower etch stop layer 140a) is slightly higher than the dielectric constant of the underlying dielectric layer (e.g., dielectric layer 130), so as to lower the capacitance of the interconnect structure of the semiconductor device.

Besides, with the disposition of the metal silicide 134 between the lowermost etch stop layer 140a and the underlying metal pattern 127, the adhesion between lowermost etch stop layer 140a and the underlying metal pattern 127 can be increased, so the device reliability can be improved.

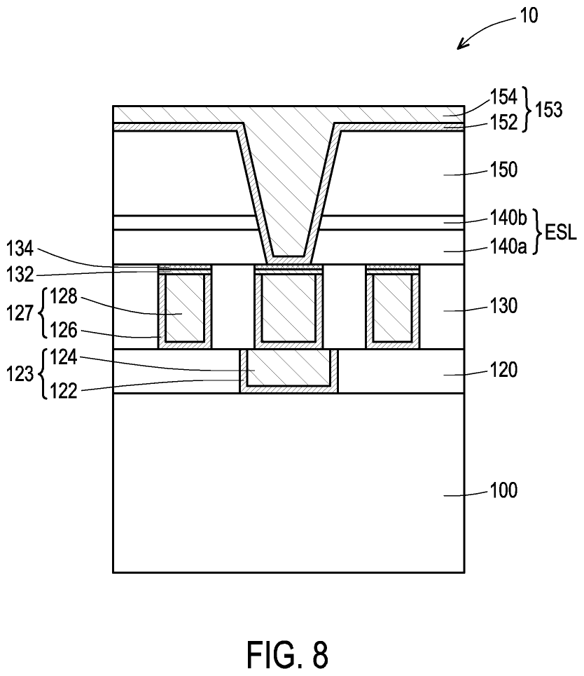

FIG. 8 further illustrates the formation of a dielectric layer 150 over the composite etch stop layer ESL. In an embodiment, the dielectric layer 150 includes a low-k material having a dielectric constant less than 3.5, less than about 3.0, less than about 2.5, or less than about 2.0. In some embodiments, the dielectric layer 150 may include carbon-doped silicon oxide, fluorine-doped silicon oxide, an organic low-k material, or a porous low-k material. In some embodiments, the dielectric layer 150 includes elements such as Si, O, C. N and/or H. For example, the low-k material includes SiOCH, SiOC, SiOCN or a combination thereof.

In some embodiments, the dielectric constant or material of the dielectric layer 150 is substantially the same as the dielectric constant or material of the dielectric layer 130. However, the disclosure is not limited thereto. In other embodiments, the dielectric constant or material of the dielectric layer 150 may be different from (e.g., greater than or less than) the dielectric constant or material of the dielectric layer 130.

FIG. 8 further illustrates the formation of at least one metal pattern 153 in the dielectric layer 150. In some embodiments, the metal pattern 153 includes a barrier layer 152 and a metal feature 154. The barrier layer 152 may be disposed between each metal feature 154 and the dielectric layer 150 to prevent the material of the metal feature 154 from migrating to the underlying component such as the transistor. The barrier layer 152 may include Ta, TaN, Ti, TiN, CoW, the like, or a combination thereof. The metal feature 154 may include copper or copper alloy. In some embodiments, a seed layer is disposed between the barrier layer 152 and each metal feature 154, and the seed layer includes Cu. In some embodiments, the metal feature 154 is referred to as a copper feature 154, although it may also be formed of, or include, another conductive material, such as silver, gold, tungsten, aluminum, or the like. In some embodiments, the method for forming the copper metal pattern 153 may include forming an opening through the dielectric layer 150 and the composite etch stop layer ESL with at least one etching process, forming a barrier material layer in the opening, depositing a thin seed layer of copper or copper alloy, and plating a copper layer in the opening. The at least one etching process includes at least one dry etching step, at least one wet etching step or a combination thereof. The metal feature 154 includes a metal line electrically connected to the metal feature 128. Throughout the description, the metal pattern 153 is referred to as a “second metal pattern”. The semiconductor structure 10 of the disclosure is thus completed.

The above embodiments in which the composite etch stop layer is a duel-layer structure are provided for illustration purposes, and are not construed as limiting the present disclosure. In other embodiments, the composite etch stop layer may be a single layer or have a third-layer structure or a fourth-layer structure upon the process requirements.

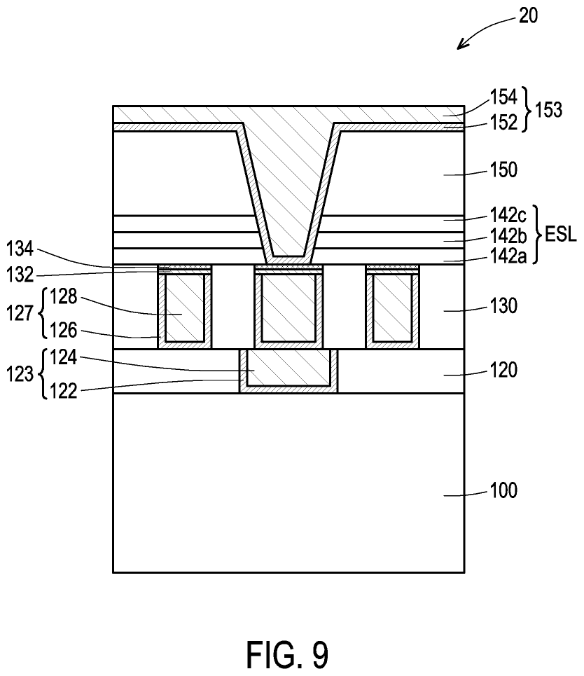

FIG. 9 to FIG. 11 are cross-sectional views illustrating semiconductor structures in accordance with other embodiments of the disclosure.

The semiconductor structure 20 of FIG. 9 is similar to the semiconductor structure 10 of FIG. 8, and the difference between them lies in the number of layers of the composite etch stop layer. As shown in FIG. 9, the composite etch stop layer ESL includes, from bottom to top, a first etch stop layer 142a, a second etch stop layer 142band a third etch stop layer 142c. In some embodiments, the first etch stop layer 142aincludes SiCN, the second etch stop layer 142b includes SiOC, and the third etch stop layer 142c includes Al₂O₃.

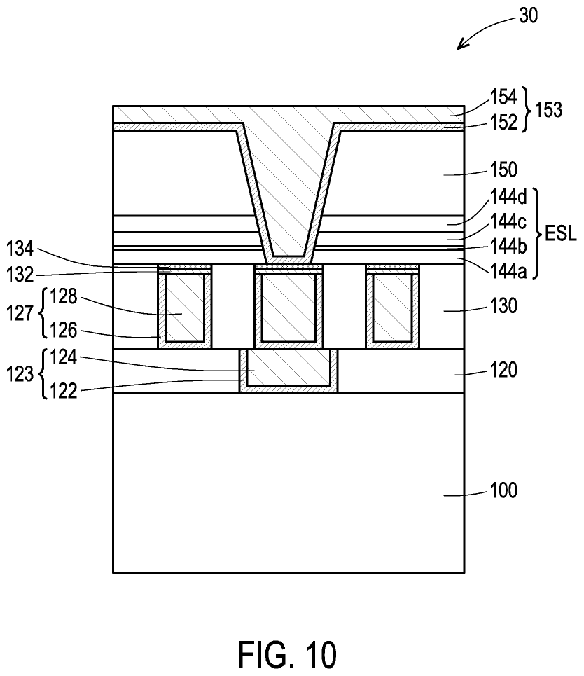

The semiconductor structure 30 of FIG. 10 is similar to the semiconductor structure 10 of FIG. 8, and the difference between them lies in the number of layers of the composite etch stop layer. As shown in FIG. 10, the composite etch stop layer ESL includes, from bottom to top, a first etch stop layer 144a, a second etch stop layer 144b, a third etch stop layer 144c, and a fourth etch stop layer 144d. In some embodiments, the first etch stop layer 144a includes SiCN, the second etch stop layer 144b includes AIN, the third etch stop layer 144c includes SiCN, and the fourth etch stop layer 144dincludes Al₂O₃. In some embodiments, the AIN layer is very thin and serves as a glue layer for the overlying SiCN.

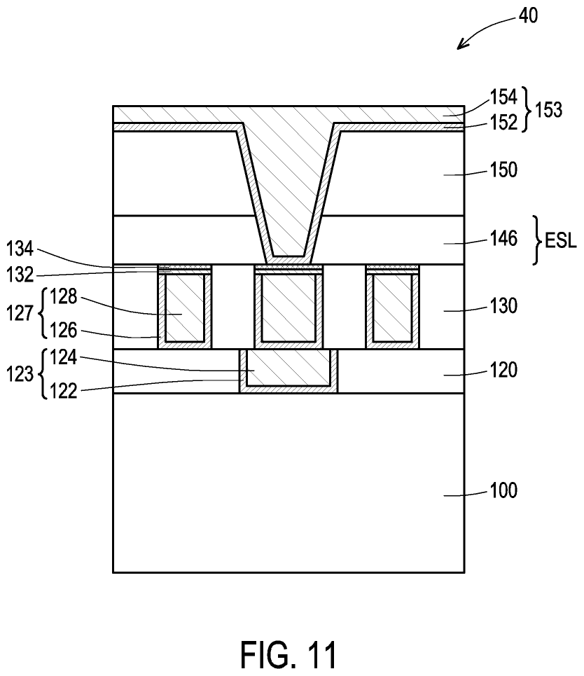

The semiconductor structure 40 of FIG. 11 is similar to the semiconductor structure 10 of FIG. 8, and the difference between them lies in the number of layers of the composite etch stop layer. As shown in FIG. 11, the composite etch stop layer ESL is a single layer including SiCN. In some embodiments, the dielectric constant of the single-layer etch stop layer ESL is substantially constant (around 4.0). In other embodiments, the dielectric constant of the single-layer etch stop layer ESL is gradually increased from 3.5 to 4.5 in a thickness direction from the underlying dielectric layer 130.

The above embodiments in which the top surface of the metal silicide pattern 134 is flushed with the top surface of the dielectric layer 130. However, the disclosure is not limited thereto. In other embodiments, the top surface of the metal silicide pattern 134 may be not flushed with (e.g., protruded from) the top surface of the dielectric layer 130.

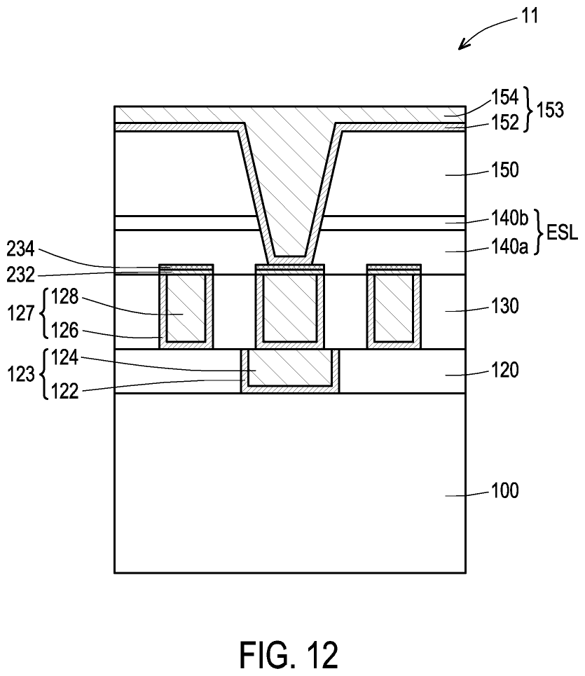

FIG. 12 to FIG. 15 are cross-sectional views illustrating semiconductor structures in accordance with other embodiments of the disclosure.

The method of forming the semiconductor structure 11 of FIG. 12 is similar to the method of forming the semiconductor structure 10 of FIG. 8, so the difference is illustrated below, and the similarity is not iterated herein.

Referring to FIG. 12, operations similar to the operations of FIG. 1 to FIG. 2 are performed, so as to provide an intermediate structure including a substrate 100, a dielectric layer 130 over the substrate 100, and a metal pattern 127 in the dielectric layer 130. The top surface of the dielectric layer 130 is flushed with the top surface of the metal pattern 127.

Thereafter, instead of the previous operation of forming a recess and filling the recess with a metal cap material described in FIG. 3, a selective growth process is performed to form a metal cap 232 on top of the metal pattern 127, so the top surface of the metal cap 232 is protruded from the top surface of the dielectric layer 130. In other embodiments, the metal cap 232 may be formed by depositing a metal cap material followed by photolithography etching processes. The metal cap 232 includes Co, Ni, Ti, W. Pt or a combination thereof. In some embodiments, the metal cap 232 has a thickness of about 10-50 angstroms, such as about 20-30 angstroms.

Afterwards, operations similar to the operations of FIG. 4 to FIG. 8 are performed, so as to form the semiconductor structure 11 of FIG. 12. In the semiconductor structure 11, the metal silicide pattern 234 is formed by siliciding the surface portion of the metal cap 232, and both the metal silicide pattern 234 and the underlying metal cap 232 are embedded by the lower etch stop layer 140a of the composite etch stop layer ESL. The metal silicide pattern 234 includes cobalt silicide (CoSix), nickel silicide (NiSx), titanium silicide (TiSix), tungsten silicide (WSix), platinum silicide (PtSix) or a combination thereof. In some embodiments, the formation of the metal silicide pattern 234 is performed in a deposition chamber, such as a plasma-enhanced chemical vapor deposition (PECVD) chamber.

The operations of forming the metal silicide pattern 234 is called a low-temperature plasma self-aligned barrier (PSAB) process. In some embodiments, the metal silicide pattern 234 has a thickness of about 2-15 angstroms, such as about 5-10 angstroms. In some embodiments, the silicon atom content of the metal silicide pattern 234 ranges from about 1 at % to 10 at %, such as from about 3 at % to 5 at %.

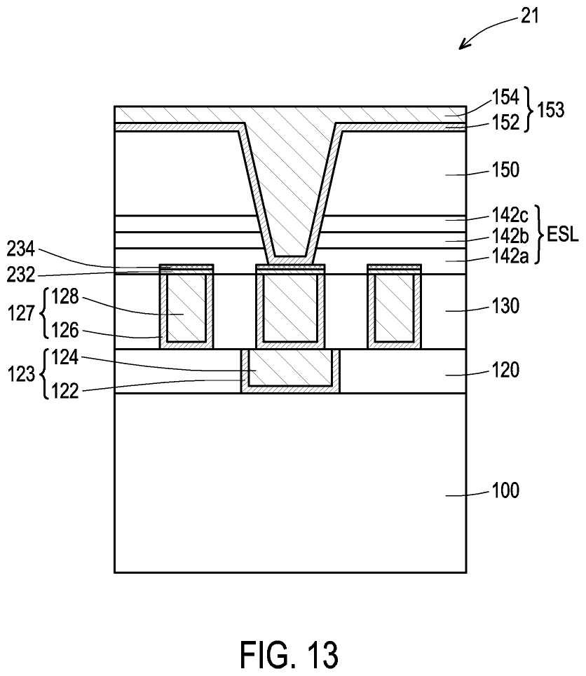

The semiconductor structure 21 of FIG. 13 is similar to the semiconductor structure 20 of FIG. 9, and the difference between them lies in the locations of the metal cap 232 and the metal silicide pattern 234. In the semiconductor structure 21 of FIG. 13, the metal cap 232 and the metal silicide pattern 234 are protruded from the top surface of the dielectric layer 130 and embedded by the composite etch stop layer ESL.

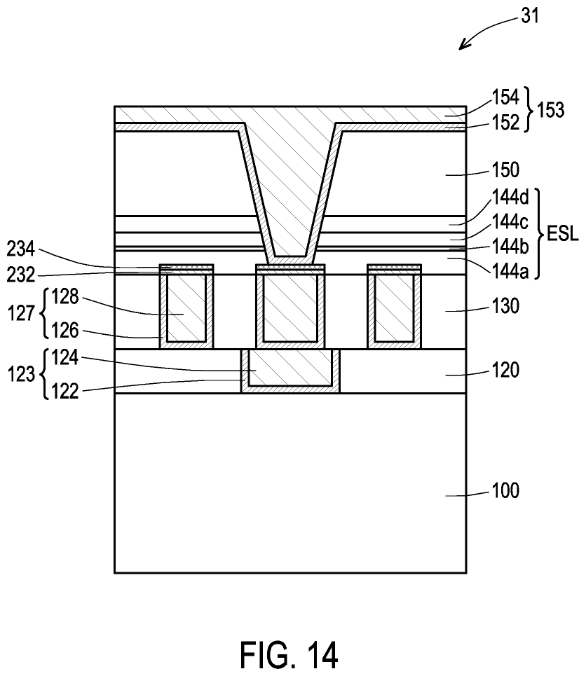

The semiconductor structure 31 of FIG. 14 is similar to the semiconductor structure 30 of FIG. 10, and the difference between them lies in the locations of the metal cap 232 and the metal silicide pattern 234. In the semiconductor structure 31 of FIG. 14, the metal cap 232 and the metal silicide pattern 234 are protruded from the top surface of the dielectric layer 130 and embedded by the composite etch stop layer ESL.

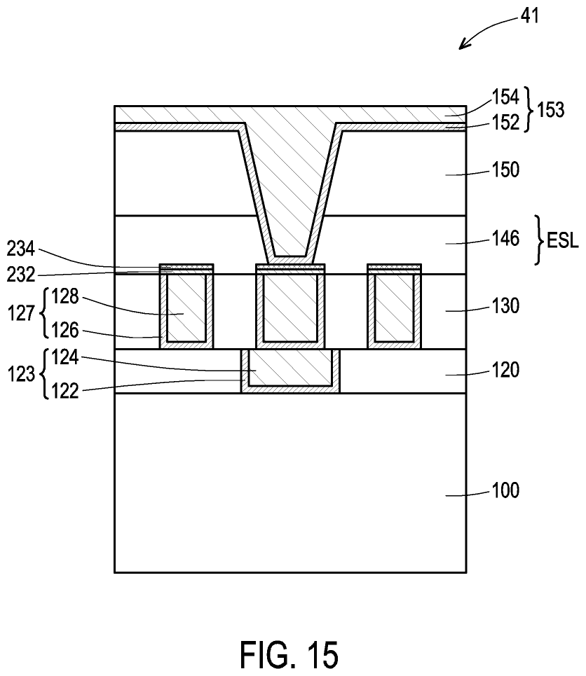

The semiconductor structure 41 of FIG. 15 is similar to the semiconductor structure 40 of FIG. 11, and the difference between them lies in the locations of the metal cap 232 and the metal silicide pattern 234. In the semiconductor structure 41 of FIG. 15, the metal cap 232 and the metal silicide pattern 234 are protruded from the top surface of the dielectric layer 130 and embedded by the composite etch stop layer ESL.

The semiconductor structures of the disclosure are described below with reference to FIG. 8 to FIG. 15.

In some embodiments, the semiconductor structure 10/11/20/21/30/31/40/41 includes a first dielectric layer 130, a first metal pattern 127, a metal cap 132/232, a metal silicide pattern 134/234 and a composite etch stop layer ESL. The first dielectric layer 130 is disposed over a substrate 100. The first metal pattern 127 is disposed in the first dielectric layer 130. The metal cap 132/232 is disposed over the first metal pattern 127. The metal silicide pattern 134/234 is disposed on the metal cap 132/232. The composite etch stop layer ESL is disposed on the first dielectric layer 130, and the composite etch stop layer ESL is in contact with the metal silicide pattern 134/234.

In some embodiments, the metal cap 132/232 is in contact with the metal silicide pattern 134/234 and the first metal pattern 127. In some embodiments, the metal cap 132/232 includes Co, Ni, Ti, W. Pt or a combination thereof. In some embodiments, the metal silicide pattern 134/234 includes cobalt silicide (CoSix), nickel silicide (NiSx), titanium silicide (TiSix), tungsten silicide (WSix), platinum silicide (PtSix) or a combination thereof.

In some embodiments, the composite etch stop layer ESL includes at least two of SiOC, SiCN, SiC, SIN, AIN, Al₂O₃ and a combination thereof. In other embodiments, the composite etch stop layer ESL is a single material layer.

In some embodiments, a dielectric constant of the first dielectric layer is lower than a dielectric constant of the lowermost etch stop layer of the composite etch stop layer by about 10-40%.

In some embodiments, a sidewall of the metal silicide pattern 134/234 is flushed with a sidewall of the metal cap 132/232 or sidewall of the first metal pattern 127.

The above embodiments, the metal silicide pattern is formed by siliciding the metal cap over the metal pattern, but the disclosure is not limited thereto. In other embodiments, the metal silicide pattern may be formed by siliciding the metal pattern directly.

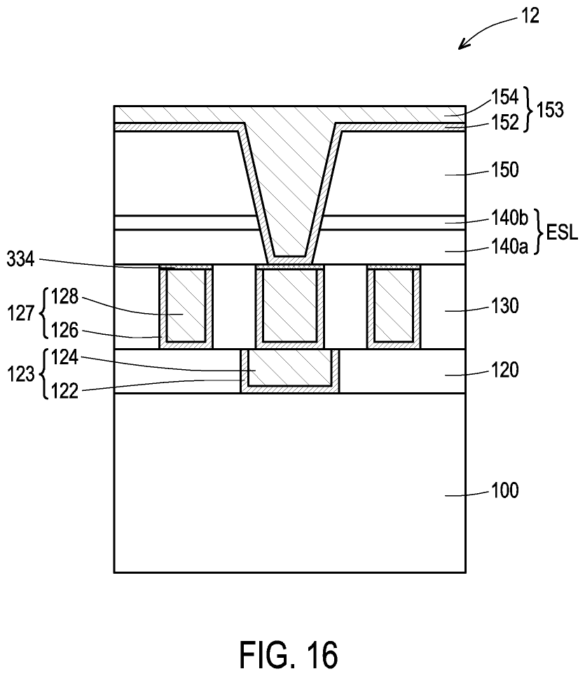

FIG. 16 to FIG. 19 are cross-sectional views illustrating semiconductor structures in accordance with other embodiments of the disclosure.

The method of forming the semiconductor structure 12 of FIG. 16 is similar to the method of forming the semiconductor structure 10 of FIG. 8, so the difference is illustrated below, and the similarity is not iterated herein.

Referring to FIG. 16, operations similar to the operations of FIG. 1 to FIG. 2 are performed, so as to provide an intermediate structure including a substrate 100, a dielectric layer 130 over the substrate 100, and a metal pattern 127 in the dielectric layer 130. The top surface of the dielectric layer 130 is flushed with the top surface of the metal pattern 127.

Afterwards, operations similar to the operations of FIG. 4 to FIG. 8 are performed directly to the surface of the metal pattern 127, so as to silicidize the surface portion of the metal pattern 127 to form a metal silicide pattern 334 on the remaining metal pattern 127. In some embodiments, both the metal silicide pattern 334 and the underlying metal pattern 127 are embedded by the dielectric layer 130. In some embodiments, the metal silicide pattern 334 includes copper silicide (CuSix). Depending on the metal of metal pattern 127, metal silicide pattern 334 may include cobalt silicide (CoSix), nickel silicide (NiSx), titanium silicide (TiSix), tungsten silicide (WSix), platinum silicide (PtSix) or a combination thereof. In some embodiments, the formation of the metal silicide pattern 334 is performed in a deposition chamber, such as a plasma-enhanced chemical vapor deposition (PECVD) chamber.

The operations of forming the metal silicide pattern 334 is called a low-temperature plasma self-aligned barrier (PSAB) process. In some embodiments, the metal silicide pattern 334 has a thickness of about 2-15 angstroms, such as about 5-10 angstroms. In some embodiments, the silicon atom content of the metal silicide pattern 334 ranges from about 1 at % to 10 at %, such as from about 3 at % to 5 at %.

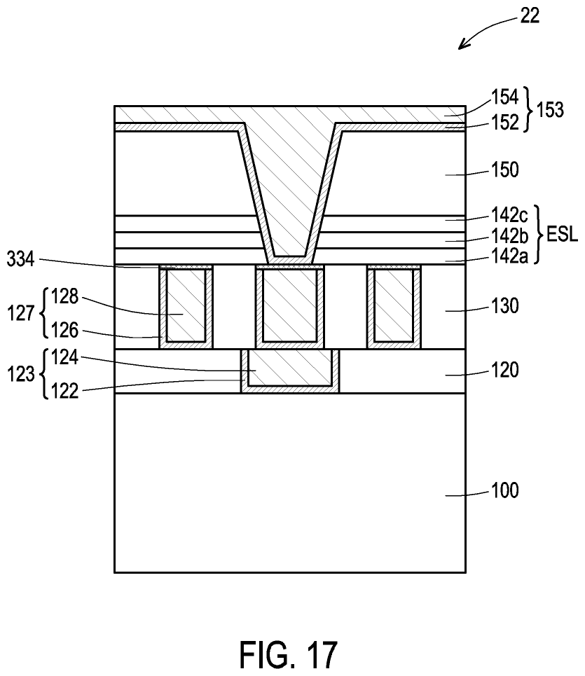

The semiconductor structure 22 of FIG. 17 is similar to the semiconductor structure 20 of FIG. 9, and the difference between them lies in the location the metal silicide pattern. In the semiconductor structure 22 of FIG. 17, the metal silicide pattern 334 is in direct contact with the metal pattern 127 without a metal cap therebetween.

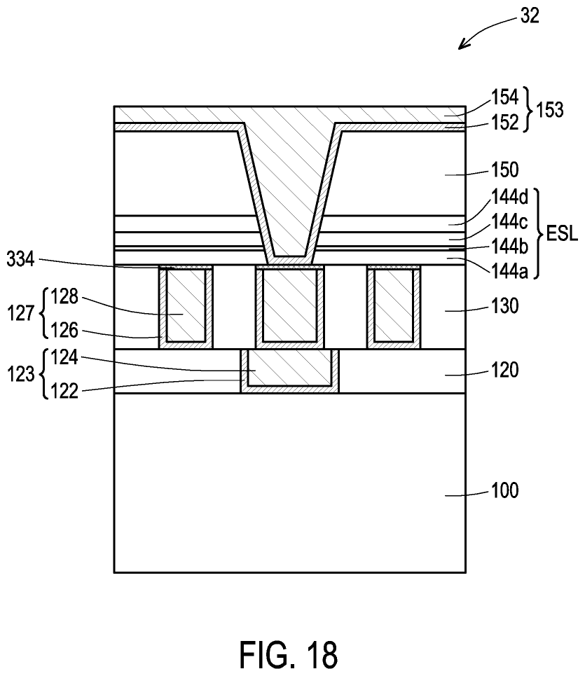

The semiconductor structure 32 of FIG. 18 is similar to the semiconductor structure 30 of FIG. 10, and the difference between them lies in the location the metal silicide pattern. In the semiconductor structure 32 of FIG. 18, the metal silicide pattern 334 is in direct contact with the metal pattern 127 without a metal cap therebetween.

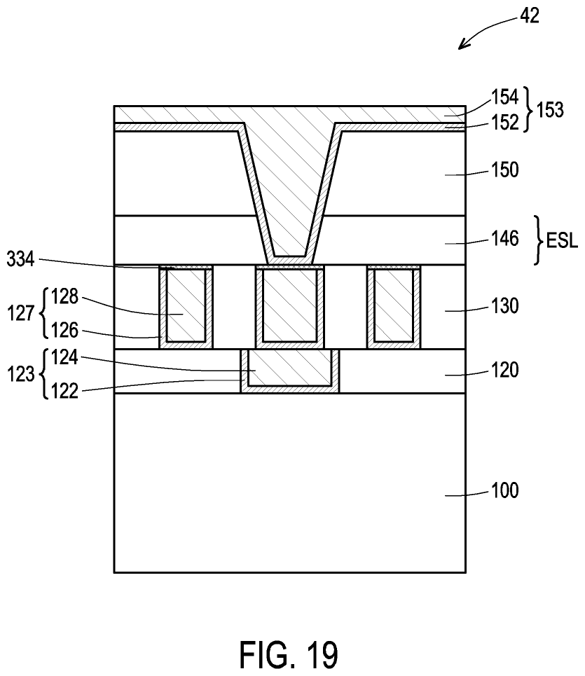

The semiconductor structure 42 of FIG. 19 is similar to the semiconductor structure 40 of FIG. 11, and the difference between them lies in the location the metal silicide pattern. In the semiconductor structure 42 of FIG. 19, the metal silicide pattern 334 is in direct contact with the metal pattern 127 without a metal cap therebetween.

In view of above, in some embodiments of the disclosure, a metal silicide is interspersed between a metal pattern and an overlying etch stop layer, so as to increase the adhesion between the metal pattern and the overlying etch stop layer, and therefore improve the reliability (e.g., time dependent dielectric breakdown (TDDB) window and the RC delay) of the semiconductor structure. Besides, the manufacturing method of the disclosure can be easily integrated with the existing process, so as to achieve competitive advantages.

In accordance with some embodiments of the disclosure, a method of forming a semiconductor structure is provided. A first dielectric layer is provided. A first metal pattern is formed in the first dielectric layer. A metal cap is formed over the first metal pattern. A surface portion of the metal cap is silicided to form a metal silicide pattern. A composite etch stop layer is formed on the first dielectric layer and the metal silicide pattern. A second dielectric layer is formed on the composite etch stop structure. A second metal pattern is formed through the second dielectric layer and the composite etch stop structure and landed on the metal silicide pattern.

In accordance with other embodiments of the disclosure, a method of forming a semiconductor structure is provided. A first dielectric layer is formed over a substrate. A first metal pattern penetrates through the first dielectric layer. A metal silicide pattern is formed over the first metal pattern. A composite etch stop layer is formed on the first dielectric layer and in contact with the metal silicide pattern.

In accordance with other embodiments of the disclosure, a semiconductor structure includes a first dielectric layer, a first metal pattern, a metal cap, a metal silicide pattern and a composite etch stop layer. The first dielectric layer is disposed over a substrate. The first metal pattern is disposed in the first dielectric layer. The metal cap is disposed over the first metal pattern. The metal silicide pattern is disposed on the metal cap. The composite etch stop layer is disposed on the first dielectric layer, and the composite etch stop layer is in contact with the metal silicide pattern.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a first dielectric layer over a substrate;
forming a first metal pattern penetrating through the first dielectric layer;
forming a metal cap over the first metal pattern;
siliciding a surface portion of the metal cap to form a metal silicide pattern;
forming a composite etch stop layer on the first dielectric layer and the metal silicide pattern;
forming a second dielectric layer on the etch stop structure; and
forming a second metal pattern penetrating through the second dielectric layer and the composite etch stop structure and landed on the metal silicide pattern.

2. The method of claim 1, wherein siliciding the surface portion of the metal cap comprises:
introducing a silicon-containing gas to contact a surface of the metal cap; and
performing a plasma process to react silicon ions of the silicon-containing gas with metal of the surface portion of the metal cap.

3. The method of claim 2, wherein the silicon-containing gas comprises SiH₄, Si(CH₃)₄, Si(CH₃)₄, Si(CH₃)₃H, Si(CH₃)₂H₂, Si₂H₆, Si₃H₈ or a combination thereof.

4. The method of claim 2, wherein a gas in the plasma process comprises NH₃, N₂, H₂, Ar or a combination thereof.

5. The method of claim 2, wherein the plasma process is performed at a temperature from 360° C. to 450° C.

6. The method of claim 2, further comprising, before introducing the silicon-containing gas to contact the surface of the metal cap, performing a pre-heating and pre-cleaning process to the surface of the metal cap.

7. The method of claim 6, wherein the pre-heating and pre-cleaning process is performed at a temperature from 280° C. to 350° C. under a nitrogen-containing atmosphere.

8. The method of claim 1, wherein the first metal pattern comprises Cu, and the metal cap comprises Co, Ni, Ti, W, Pt or a combination thereof.

9. A method of forming a semiconductor structure, comprising:
providing a first dielectric layer;
forming a first metal pattern in the first dielectric layer;
forming a metal silicide pattern over the first metal pattern; and
forming a composite etch stop layer on the first dielectric layer and in contact with the metal silicide pattern.

10. The method of claim 9, further comprising forming a metal cap between the first metal pattern and the metal silicide pattern.

11. The method of claim 10, wherein forming the metal cap comprises:
removing a portion of the first metal pattern to form a recess above the remaining first metal pattern; and
filling the recess with the metal cap.

12. The method of claim 10, wherein forming the metal cap comprises:
performing a selective growth process to form the metal cap over the first metal pattern.

13. The method of claim 10, wherein the metal silicide pattern is formed by siliciding metal in the metal cap.

14. The method of claim 9, wherein a dielectric constant of the first dielectric layer is lower than a dielectric constant of the lowermost etch stop layer of the composite etch stop layer by about 10-40%.

15. A semiconductor structure, comprising:
a first dielectric layer disposed over a substrate;
a first metal pattern disposed in the first dielectric layer;
a metal cap disposed over the first metal pattern;
a metal silicide pattern disposed over the metal cap; and
a composite etch stop layer disposed on the first dielectric layer and in contact with the metal silicide pattern.

16. The semiconductor structure of claim 15, wherein a top surface of the metal silicide pattern is flushed with or higher than a top surface of the first dielectric layer.

17. The semiconductor structure of claim 15, wherein the metal cap comprises Co, Ni, Ti, W, Pt or a combination thereof.

18. The semiconductor structure of claim 15, wherein the composite etch stop layer comprises at least two of SiOC, SiCN, SiC, SIN, AIN, Al₂O₃ and a combination thereof.

19. The semiconductor structure of claim 15, wherein a dielectric constant of the first dielectric layer is lower than a dielectric constant of a lowermost etch stop layer of the composite etch stop layer by about 10-40%.

20. The semiconductor structure of claim 15, wherein a sidewall of the metal silicide pattern is flushed with a sidewall of the first metal pattern.
